(19) United States
(12) Patent Application Publication
(10) Pub. No.: US 2024/0250506 A1
(43) Pub. Date: Jul. 25, 2024

(54) LASER BAR WITH REDUCED LATERAL FAR-FIELD DIVERGENCE

(71) Applicant: FERDINAND-BRAUN-INSTITUT GGMBH LEIBNIZ-INSTITUT FÜR HÖCHSTFREQUENZTECHNIK, Berlin (DE)

(72) Inventors: Mathias M. KAROW, Berlin (DE); Paul CRUMP, Berlin (DE); Mohammad Jarez MIAH, Berlin (DE)

(73) Assignee: FERDINAND-BRAUN-INSTITUT GGMBH LEIBNIZ-INSTITUT FÜR HÖCHSTFREQUENZTECHNIK, Berlin (DE)

(21) Appl. No.: 18/566,289

(22) PCT Filed: Jun. 2, 2022
(86) PCT No.: PCT/EP2022/065024

§ 371 Date: Dec. 1, 2023

(30) Foreign Application Priority Data
Jun. 3, 2021 (DE) 10 2021 114 411.6

(51) Int. Cl. H01S 5/40; H01S 5/024; H01S 5/028; H01S 5/06

(52) U.S. Cl. CPC H01S 5/4025; H01S 5/02469; H01S 5/0287; H01S 5/0612

(57) ABSTRACT

The present invention relates to a laser bar with reduced lateral far-field divergence and, more particularly, to a laser bar with a uniform temperature profile in the lateral direction to reduce lateral far-field divergence.

A laser bar (1) according to the invention comprises a plurality of emitter structures arranged in parallel next to one another in the lateral direction, wherein, for the variation of the temperature profile in lateral direction, an adjustment of the dissipated thermal power of the outer emitter structures is made with respect to the inner emitter structures enclosed by the outer emitter structures.

The present invention relates to a laser bar with reduced lateral far-field divergence and, more particularly, to a laser bar with a uniform temperature profile in the lateral direction for reducing lateral far-field divergence.

### STATE OF THE ART

Laser bars typically consist of several broad-area diode lasers (BALs) arranged in parallel on a common substrate in the lateral direction. Thus, total output powers of 1500 W and more can be achieved. The number of broad-area diode lasers arranged in a laser bar can vary; typical values are between 5 and 200. The lateral stripe width of the broad-area diode lasers is typically between 5 μm and 100 μm, but can also be significantly larger, such as 1200 μm.

Usually, the individual laser elements are formed as separate emitter structures in a common layer structure, whereby a structuring of the charge carrier supply is usually carried out for a separation of the emitter structures, in particular via a structuring of the p-contact layer opposite an n-substrate and of the associated p-contacts. Via the p and n contacts, charge carriers are injected into the active zone formed between the two contacts within the layer structure. Since the injected charge carriers move predominantly along a direct path without lateral current expansion in the direction of the active zone, the radiation generation within the active zone can also be structured accordingly in the lateral direction by means of appropriate separating structures in the charge carrier supply. As local separating structures for the separation of the individual emitter structures, an implantation of impurities or foreign atoms, the formation of trenches or the local introduction of dielectric sections (e.g. created by filling the trenches with a dielectric material) is usually carried out in the p-contact layer.

In the case of a conventional laser bar, structuring of the p contact layer in particular thus generates a plurality of identical emitter structures. The radiation emitted by these emitter structures should thus have largely identical properties. Although the individual emitter structures are identical in structure, in laser bars with a high fill factor and small distances between the individual emitter structures, however, a different temperature distribution is established for the outer emitter structures than for the inner emitter structures of the laser bar. The inner emitter structures show a largely similar temperature profile with a uniform maximum temperature and little temperature modulation in the region between the emitter structures due to the strong thermal coupling between them. The temperature profile for the outer emitter structures, on the other hand, is strongly asymmetric and the maximum temperatures drop unilaterally due to the lack of thermal contribution from emitter structures located further out.

It has been found by the inventors that such an asymmetric temperature profile results in the lateral far-field divergence of the outer emitter structures being broader than that of the inner emitter structures, which contributes significantly to the broadening of the overall bar far-field divergence. Thereby, up to ⅔ of the emitter structures in a laser bar can be affected by such asymmetric temperature profiles and the resulting far-field broadening.

### DISCLOSURE OF THE INVENTION

It is therefore a task of the present invention to provide a laser bar in which a reduction of the lateral far-field divergence can be achieved by a variation of the temperature profile in lateral direction. In particular, such variation of the temperature profile in the lateral direction is intended to adapt the temperature of the outer emitter structures to a temperature of the inner emitter structures enclosed by the outer emitter structures. By novel bar designs and arrangements, the lateral temperature distributions within the outer emitters can be adjusted to be as close as possible to those of the inner emitters. In this way, the formation of an asymmetric temperature profile and the occurrence of a resulting broadening of the lateral far-field divergence can be avoided.

These tasks are solved according to the invention by the features of patent claim 1. Practical embodiments of the invention are contained in the respective sub claims.

A laser bar according to the invention comprises a layer system of a semiconductor material with an active layer, wherein the layer system has an n-contact and p-contact for the injection of charge carriers into the active layer, wherein a plurality of emitter structures arranged in parallel next to one another is formed by structuring the layer system, the emitter structures extending in the longitudinal direction between a front facet and a rear facet and in the lateral direction from a first side to a second side, and the emitter structures each being separated from one another by a separating structure extending in the longitudinal direction for structuring purposes. For a variation of the temperature profile in lateral direction provided according to the invention, an adjustment of the dissipated thermal power of the outer emitter structures facing the first side and the second side, respectively, with respect to the inner emitter structures enclosed by the outer emitter structures is made. In particular, a largely homogeneous temperature profile with respect to the maximum temperature of the individual emitter structures during operation of the laser bar can be achieved by the adjustment in lateral direction.

The layer system of a laser bar according to the invention may comprise, for example, an n-contact (e. g. formed as a metallic contact surface); an n-substrate, wherein the n-substrate is arranged on the n-contact; an n-cladding layer, wherein the n-cladding layer is arranged on the n-substrate; an n-waveguide layer, wherein the n-waveguide layer is arranged on the n-cladding layer; an active layer, the active layer being disposed on said n-waveguide layer; a p-waveguide layer, the p-waveguide layer being disposed on the active layer; a p-cladding layer, the p-cladding layer being disposed on the p-waveguide layer; a structured p-contact layer, wherein the p contact layer is arranged on the p-cladding layer and by the structuring forms a plurality of emitter structures arranged in parallel next to one another, wherein for the structuring in the p-contact layer the regions between the emitter structures are separated from one another, respectively, by a separating structure and the emitter structures extend in the longitudinal direction between a front facet and a rear facet and in the lateral direction from a first side (e.g. left) to a second side (e.g. right); and a plurality of p-contacts (e.g. formed as metallic contact elements), the p-contacts 5 resting on the structures of the p-contact layer 10 and enabling injection of charge carriers into the respective emitter structures.

The idea of the invention is thus to provide a laser bar with reduced lateral far-field divergence in which a variation of the temperature profile in the lateral direction is effected by adjusting the dissipated thermal power (local heat) of the outer emitter structures facing the first side and the second side, respectively, with respect to the inner emitter structures enclosed by the outer emitter structures. In contrast to conventional laser bars according to the state of the art, the individual emitter elements are thus not formed identically to each other, but in order to reduce the lateral far-field divergence, some of the emitter elements can be modified by suitable measures in such a way that their dissipated thermal power is adjusted. In this way, in particular, a variation of the temperature profile in the lateral direction can take place to adapt the temperature of the outer emitter structures to a temperature of the inner emitter structures enclosed by the outer emitter structures.

Preferably, an adjustment of the dissipated thermal power of the outer emitter structures is made gradually over several adjacent outer emitter structures. Indeed, it could be shown by the inventors that already the adjustment of the dissipated thermal power d of the respective outermost emitter elements of a laser bar can lead to a significant adjustment of the temperature profile in lateral direction. Depending on the laser bar design, however, improved adjustment can be achieved by adjusting the dissipated thermal power accordingly for neighboring emitter structures in addition to the respective outermost emitter structures. Particularly preferably, the strength of the adjustment decreases in the direction towards the inner emitter structures. An adjustment of the dissipated thermal power of the outer emitter structures gradually across several adjacent outer emitter structures can specifically take place, for example, across three or four or more of the outer emitter elements in each case.

Preferably, to increase the dissipated thermal power, the electrical and/or optical properties of the outer emitter structures are adjusted compared to the inner emitter structures. The dissipated thermal power can be increased in particular by increasing the losses within the outer emitter structures. For this purpose, essentially optical (i.e. concerning the radiation conduction), essentially electrical (i.e. concerning the current conduction) or mixed (i.e. concerning the radiation conduction and the current conduction) adjustments can be made.

An effective way to adjust the electrical and/or optical properties of the emitters, and thus increase the dissipated thermal power, is to modify the outer emitter structures (i.e., the optical resonator formed within the emitter structures). In particular, for adjustment, higher optical powers can be included within the outer emitter structures, heat removal from the outer emitter structures can be degraded, additional internal optical losses (e.g., scattering losses) can be introduced to the outer emitter structures, the effectiveness of the active zones of the outer emitter structures can be degraded, and/or high impedance structures can be introduced into the emitter structures (particularly the inner emitter structures).

Preferably, to increase the internal resonator losses for the outer emitter structures, the facet reflectivity of the outer emitter structures is increased with respect to the facet reflectivity of the inner emitter structures. It has been shown that an effective way to adjust the emitted thermal power of the emitter elements is to change the facet reflectivity of the emitter structures (i.e., the optical resonator formed within the emitter structures). Thereby, a higher facet reflectivity leads to an increase of the optical power stored in the emitter structures, which in turn leads to an increase of the internal resonator losses and thus also to an increase of the temperature of the respective emitter structures.

Preferably, the facet reflectivity d of the emitter structures can be adjusted by reflectors by means of an integration of distributed Bragg reflectors (DBR), in particular front-side DBR and/or rear-side DBR, or by applying dielectric mirror layers to the front facets and/or the rear facets. The facet reflectivity can thereby be adjusted via the reflectivity of the reflector elements. The adjustment of the optical properties of a resonator by adjusting the reflectivities at the ends is known to those skilled in the art per se, but this dependence is used here to selectively adjust the temperature of individual emitter elements of a laser bar to reduce the lateral far-field divergence.

By adjusting the facet reflectivity, the intensity of the light enclosed in the emitter structures (or the light coupled out, also known as mirror loss) can be controlled. As the reflectivities of the outer emitter structures increase, their reflector losses decrease, more optical energy is stored in the emitter structures, and thus the heat input inside the emitter structures also increases. Increased heat input also increases the temperature of the outer emitter structures.

Preferably, the reflectivity of a front-side reflector (R_{f}) of the outer emitter structures is between 1% and 30%, especially preferably between 1% and 12%. This range of values results for typical laser bars from the measured temperature drop at the outer emitter structures. With these values for reflectivity, an increase in temperature in the range of up to 10 K can typically be achieved compared to emitter structures without additional reflectors.

Preferably, to increase the thermal resistance (Rₜₕ) of the outer emitter structures relative to the inner emitter structures, the length of the pumped region of the outer emitter structures is shortened relative to the length of the pumped region of the inner emitter structures by forming non-pumped regions. It was shown that another effective way to adjust the emitted thermal power for the emitter elements is to change the thermal resistance of the emitter structures. Increased thermal resistance reduces heat dissipation from the emitter structures and can thus also lead to an increase in the temperature of the respective emitter structures.

Preferably, for the outer emitter structures, the length of the pumped region with respect to the length of the pumped region of the inner emitter structures is between 90% and 20%, more preferably between 80% and 35%. For example, a typical length for the pumped region of an inner emitter structure is 4 mm and corresponds to the length of the resonator. The length of the pumped region of the outer emitter structures can then be shortened to, for example, 1.4 mm for a typically required temperature rise for these emitter structures.

Shortening the length of the pumped region by introducing one or more non-pumped regions within the outer emitter structures as opposed to the inner emitter structures can reduce the heat dissipation capability of the outer emitter structures. By shortening the pumped region the series resistance and thermal resistance increase. The series resistance increases as the pump length decreases (L_{gain}<Lᵣₑₛₒₙₐₜₒᵣ) according to the formula Rₛ=ρₛ/(wL_{gain}), while the series resistance of the inner emitters follows Rₛ=ρs/(wLᵣₑₛₒₙₐₜₒᵣ). Due to the increased electrical series resistance, the maximum current through the outer emitter structures (at constant applied voltage) decreases, and thus the thermal output of the emitter structures decreases. However, the excessively increased thermal resistance increases the overall temperature within these emitter structures.

Preferably, non-pumped regions are formed adjacent to the front facet and the rear facet. A symmetrical arrangement of the non-pumped regions is preferred. However, the position of the pumped regions along the longitudinal axis of the emitter structures can be freely selected and individually determined for different emitter structures.

To create a non-pumped region, in the simplest case, deposition of contact metal on these regions can be suppressed. As a result, most of the current is confined to the sections with contact metal above them. However, some of the injected charge carriers may propagate and still diffuse into the non-pumped regions.

Preferably, to reduce charge carrier propagation in the non-pumped passive regions, inert ions are implanted by deep ion implantation. It has been shown that the non-pumped regions can be formed more effectively by implantation of inert ions. The depth of implantation can be limited to implantation up into the p-contact layer. However, implantation can also extend beyond the p-contact layer into the p-waveguide layer. Ion implantation or deep ion implantation removes the conductivity of the highly p-doped contact, cladding and waveguide layers. On the one hand, ion implantation can thus restrict the flow of charge carriers to the pumped regions. On the other hand, it also prevents the charge carriers from diffusing into the non-pumped regions.

Preferably, to increase the internal optical losses (aint) at the outer emitter structures loss elements are formed. The effect of increasing internal resonator losses has already been explained above. These loss elements can be created by introducing 1-, 2- or 3-dimensional loss centers via local modification of the refractive index or by etching wave-like structures along the longitudinal direction of the laser resonator or by locally increasing the charge carrier density, e.g. by diffusing dopants into the crystal structure. Such structures cause additional scattering and absorption losses due to interaction with the laser light. The resulting reduced slope efficiency (ηₛₗₒₚₑ) of the emitter increases the power dissipation and thus causes an increase in temperature within the emitter structures.

Preferably, the internal optical losses (αᵢₙₜ) of the outer emitter structures are between 0.6 cm⁻¹ and 1.5 cm⁻¹, more preferably between 1 cm⁻¹ and 1.5 cm⁻¹, and even more preferably between 1.2 cm⁻¹ and 1.5 cm⁻¹. The internal optical losses for epitaxial materials typically used for high power laser diodes is approximately between 0.3 cm⁻¹ and 0.4 cm⁻¹.

Preferably, in order to increase the thermal power of the outer emitter structures compared to the inner emitter structures, inert ions are implanted at least in sections in the direction of the active layer in the outer emitter structures to increase the non-radiative recombination and thus to reduce the internal quantum efficiency (ηᵢₙₜ). Due to the resulting selective charge carrier losses, the internal quantum efficiency in these emitter structures can be lowered, thus worsening the power conversion efficiency (PCE) of the outer emitter structures. To realize this, at least individual regions of the semiconductor materials can be deep implanted with inert ions. Due to the defects introduced near the active gain materials during deep implantation, the non-radiative recombination increases compared to the radiative recombination. Consequently, thermal power dissipation increases within the modified emitter structures. Degradation of the internal quantum efficiency increases the internal heating by enhancing the nonradiative recombination and thus decreasing the power conversion efficiency.

The emitter structure can be designed as an arrangement of implanted and non-implanted regions. A symmetrical arrangement of the implanted and non-implanted regions is preferred, and in particular the individual regions can each have the same lengths. However, the position and length of the implanted and non-implanted regions along the longitudinal axis of the emitter structures can be freely chosen and individually determined for different emitter structures. The depth of the implantation preferably extends from the p-contact layer through the p-cladding layer, p-waveguide layer and active layer down to the n-waveguide layer.

Preferably, sufficient defects are introduced into the outer emitter structures such that the internal quantum efficiencies (ηᵢₙₜ) of the outer emitter structures are between 50% and 92%, more preferably between 84% and 92%. The internal quantum efficiency typically achievable for epitaxial materials commonly used for high power laser diodes is approximately between 95% and 100%.

Preferably, to increase the series resistance (ρₛ) of the inner emitter structures, inert ions are implanted at least in sections in the direction of the active layer. By increasing the series resistance of the inner emitter structures, a higher current flow through the outer emitters can be forced, thereby causing additional heating of the outer emitter structures. To increase the series resistance of the inner emitters, preferably parts of the semiconductor materials, e.g. their contact region, can be implanted with inert ions. In contrast to the previously described embodiment of a current blocking ion implantation, the purpose of the ion implantation is to increase the series resistance ρₛ, while the pump length L_{gain} continues to correspond to the resonator length (L_{gain}=Lᵣₑₛₒₙₐₜₒᵣ). Due to the resulting increased series resistance by increasing ρₛ according to the formula Rₛ=ρₛ/(wLᵣₑₛₒₙₐₜₒᵣ) in the inner emitter structures, the amount of current flow through the outer emitter structures (at constant applied voltage) increases. Consequently, also in the inner emitter structures the high temperature of the inner emitter structures can be reached by the higher current. A symmetrical arrangement of the implanted and non-implanted regions is preferred, and in particular the individual regions can each have the same lengths.

The emitter structure can be designed as an arrangement of implanted and non-implanted regions, or the implanted region can extend over the entire length of an emitter structure.

A symmetrical arrangement of the implanted and non-implanted regions is preferred, and in particular the individual regions may each have the same lengths. However, the position and length of the implanted and non-implanted regions along the longitudinal axis of the emitter structures may be freely chosen and individually determined for different emitter structures. The depth of implantation can range from implantation only in the p-contact layer to implantation extending from the p-contact layer into the p-waveguide layer.

Preferably, the series resistance of the inner emitter structures is increased by a factor of 1.2 to 1.6 compared to the outer emitter structures.

In the tables below, for each of the above embodiments of the invention, examples of the values required to adjust the dissipated thermal power of the outer emitter structures facing the first side and the second side, respectively, with respect to the inner emitter structures enclosed by the outer emitter structures are given for a typical high-power laser. The values were determined by simulation to show the practicality of this approach. However, depending on the type of laser bar, the required adjustments may also differ significantly from the values shown here.

The tables on the left show the thermal resistance Rₜₕ in K/W, the maximum temperatures of the inner and outer emitter structures Tᵢ and Tₐ for a conventional high-power laser diode, and the resulting difference dT between the maximum temperatures of the emitter structures. In contrast, the tables on the right-hand side each show the corresponding variation parameter and its effects in the case of an adjustment according to the invention. The temperature change dT achieved by the variation, a resulting change in the power conversion efficiency ΔPCE and a factor P_{diss}, by which the dissipated thermal power in the outer emitter structures is increased by the adjustments made, are indicated.

TABLE 1

| Rₜₕ | Tᵢ (° C.) | Tₐ (° C.) | dT | R_{f} | dT | ΔPCE | ΔP_{diss} |
|---|---|---|---|---|---|---|---|
| (K/W) | @ 900 W | @ 900 W | (K) | (%) | (K) | (%) | (factor) |
| 0.05 | 60.58 | 57.08 | 3.50 | 12 | 3.68 | −4.80 | 1.16 |
| 0.2 | 73.88 | 65.40 | 8.48 | 29 | 8.64 | −11.28 | 1.37 |

Table 1 shows that with an increased reflectance R_{f} of 12% and 29% of the front facet of the outer emitter structures, respectively, a corresponding adjustment of the temperatures can be achieved. Increased reflectance R_{f} of the front facet can change the optical properties of the outer emitter structures and thus increase the optical power stored in the emitter structures. This also increases the losses that occur and thus also the temperature of the emitters.

TABLE 2

| Rₜₕ | Tᵢ (° C.) | Tₐ (° C.) | dT | L_{gain} | dT | ΔPCE | ΔP_{diss} |
|---|---|---|---|---|---|---|---|
| (K/W) | @ 900 W | @ 900 W | (K) | (μm) | (K) | (%) | (factor) |
| 0.05 | 60.58 | 57.08 | 3.50 | 1750 | 3.54 | −4.47 | 0.50 |
| 0.2 | 73.88 | 65.40 | 8.48 | 1400 | 8.54 | −10.82 | 0.47 |

Table 2 shows that by shortening the length of the pumped region L_{gain} of the outer emitter structures compared to the length of the pumped region L_{gain} of the inner emitter structures, a corresponding adjustment of the temperatures can be achieved. In this example, the length of the pumped region L_{gain} of the inner emitter structures corresponded to the resonator length 4000 μm.

TABLE 3

| Rₜₕ | Tᵢ (° C.) | Tₐ (° C.) | dT | αᵢₙₜ | dT | ΔPCE | ΔP_{diss} |
|---|---|---|---|---|---|---|---|
| (K/W) | @ 900 W | @ 900 W | (K) | (cm )⁻¹ | (K) | (%) | (factor) |
| 0.05 | 60.58 | 57.08 | 3.50 | 0.85 | 3.39 | −4.43 | 1.14 |
| 0.2 | 73.88 | 65.40 | 8.48 | 1.50 | 8.74 | −11.39 | 1.37 |

Table 3 shows that by increasing the internal optical losses aint of the outer emitters, a corresponding adjustment of the temperatures can be achieved. In particular, the internal optical losses can be increased by introducing loss elements into the emitter structures. The loss elements can be created by introducing 1-, 2- or 3-dimensional loss centers into the crystal structure.

TABLE 4

| Rₜₕ | Tᵢ (° C.) | Tₐ (° C.) | dT | | dT | ΔPCE | ΔP_{diss} |
|---|---|---|---|---|---|---|---|
| (K/W) | @ 900 W | @ 900 W | (K) | ηᵢₙₜ | (K) | (%) | (factor) |
| 0.05 | 60.58 | 57.08 | 3.50 | 0.92 | 3.76 | −4.90 | 1.16 |
| 0.2 | 73.88 | 65.40 | 8.48 | 0.84 | 8.65 | −11.28 | 1.37 |

Table 4 shows that by lowering the internal quantum efficiency ηᵢₙₜ of the external emitter structures, a corresponding adjustment of the temperatures can be achieved. In particular, the internal quantum efficiency ηᵢₙₜ can be achieved by enhancing the nonradiative recombination on injected charge carriers (i.e., electrons and holes).

TABLE 5

| Rₜₕ | Tᵢ (° C.) | Tₐ (° C.) | dT | | dT | ΔPCE | ΔP_{diss} |
|---|---|---|---|---|---|---|---|
| (K/W) | @ 900 W | @ 900 W | (K) | ρₛ | (K) | (%) | (factor) |
| 0.05 | 60.58 | 57.08 | 3.50 | 1.2 ρₛ₀ | −4.02 | −0.11 | 0.84 |
| 0.2 | 73.88 | 65.40 | 8.48 | 1.6 ρₛ₀ | −8.74 | −0.94 | 0.64 |

Table 5 shows that by increasing the series resistance ρₛ of the inner emitter structures (e.g., by implanted inert ions) by a factor of 1.2 to 1.6 compared to the series resistance ρₛ₀ of the outer emitter structures (i.e., emitters not implanted with inert ions), a corresponding adjustment of the temperature can be achieved.

Further preferred embodiments of the invention result from the features mentioned in the dependent claims.

The various embodiments of the invention mentioned in this application can be advantageously combined with each other, unless otherwise specified in the individual case.

### BRIEF DESCRIPTION OF THE DRAWINGS

The invention is explained below in embodiment examples with reference to the accompanying drawing. It shows:

FIG. 1 a schematic representation of an exemplary conventional laser bar structure in a) oblique view, b) side view and c) top view;

FIG. 2 a) lateral temperature profiles in conventional laser bars with 37 emitters for thermal resistances Rₜₕ of 0.05 K/W (left) and 0.20 K/W (right) at different operating powers Pop, b) normalized temperature profiles of the laser bars at their respective maximum operating points and c) the dependence of the lateral temperature profiles of a laser bar with Rₜₕ=0.05 K/W on the boundary heat factor BH of the outer emitter structures at their respective maximum operating points;

FIG. 3a a schematic representation of a first embodiment of a laser bar structure according to the invention in combined upward and oblique view;

FIG. 3b a dependence of the reflector loss, the slope efficiency ηₛₗₒₚₑ and the threshold current Iₜₕ as a function of the reflectance R_{f} at the front facet;

FIG. 3c a dependence of the output power Pout and the power conversion efficiency PCE on the operating current I for different reflectances R_{f} at the front facet;

FIG. 3a a dependence of the power dissipation P_{diss}, the power conversion efficiency PCE and the temperature rise dT in the active zone (dT=T_{active zone}−T_{heat sink}) as a function of the reflectance R_{f} at the front facet at maximum operating voltage (˜1.55 V);

FIG. 4 a schematic representation of a second embodiment of a laser bar structure according to the invention in combined upward and oblique view,

FIG. 5 a schematic representation of a third embodiment of a laser bar structure according to the invention in combined upward and oblique view,

FIG. 6 a schematic representation of a fourth embodiment of a laser bar structure according to the invention in combined upward and oblique view,

FIG. 7 a schematic representation of a fifth embodiment of a laser bar structure according to the invention in combined upward and oblique view,

FIG. 8 a schematic representation of a sixth embodiment of a laser bar structure according to the invention in combined upward and oblique view, and

FIG. 9 a schematic representation of a seventh embodiment of a laser bar structure according to the invention in combined upward and oblique view.

### DETAILED DESCRIPTION OF THE DRAWINGS

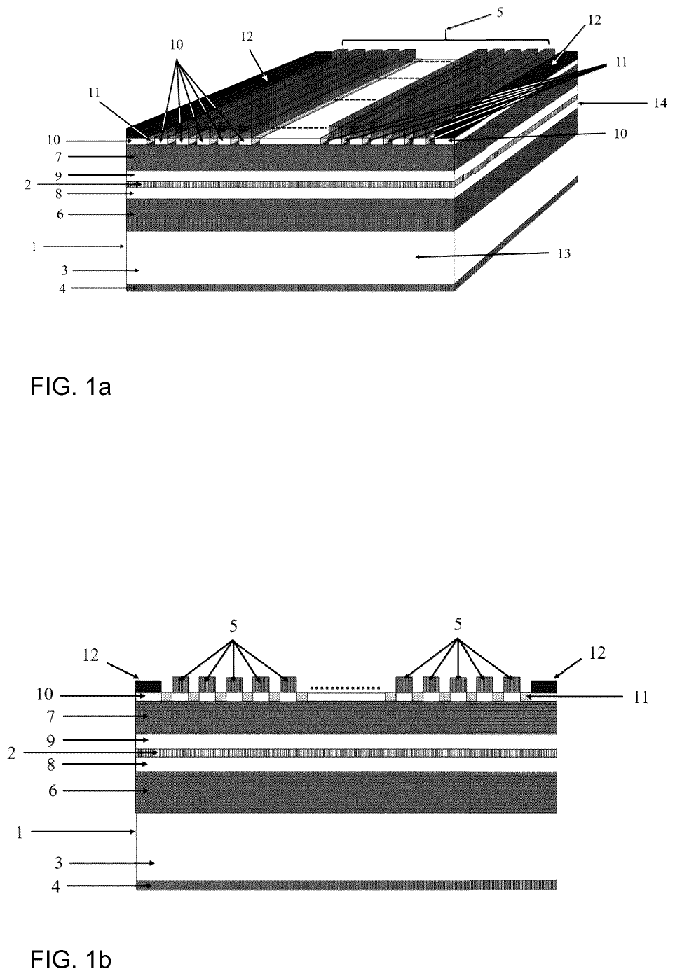

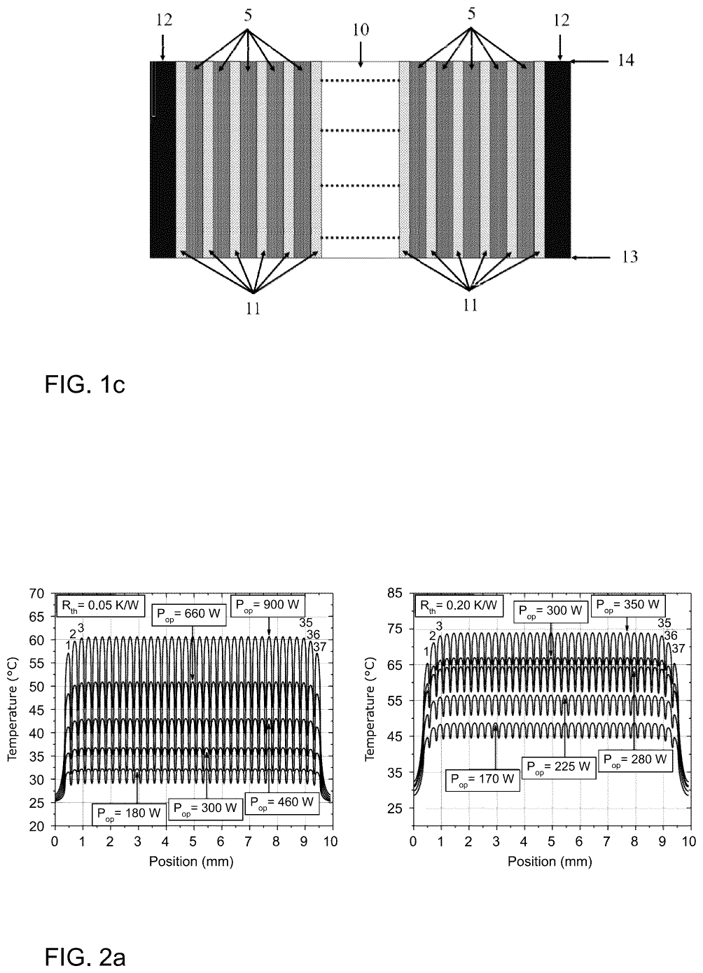

FIG. 1 shows a schematic representation of an exemplary conventional laser bar structure in a) oblique view, b) side view and c) top view. The laser bar 1 comprises an n-contact 4 (e.g. formed as a metallic contact surface); an n-substrate 3, wherein the n-substrate 3 is disposed on the n-contact 4; an n-cladding layer 6, wherein the n-cladding layer 6 is disposed on the n-substrate 3; an n-waveguide layer 8, wherein the n-waveguide layer 8 is disposed on the n-cladding layer 6; an active layer 2, wherein the active layer 2 is disposed on the n-waveguide layer 8; a p-waveguide layer 9, wherein the p-waveguide layer 9 is disposed on the active layer 2; a p-cladding layer 7, wherein the p-cladding layer 7 is disposed on the p-waveguide layer 9; a structured p-contact layer 10, the p-contact layer 10 being arranged on the p-cladding layer 7 and forming, by the structuring, a plurality of emitter structures arranged parallel next to one another, wherein, for the purpose of structuring in the p-contact layer 10, the regions between the emitter structures are in each case separated from one another by a separating structure 11 and the emitter structures extend in the longitudinal direction between a front facet 13 and a rear facet 14 and in the lateral direction from a first side (e.g. left) to a second side (e.g. right); and a plurality of p-contacts 5 (e.g. formed as metallic contact elements), the p-contacts 5 resting on the structures of the p-contact layer 10 and allowing charge carriers to be injected into the respective emitter structures n.

The termination to the two outer sides of the laser bar 1 is typically formed in each case by a non-active blind emitter 12, which can be designed in particular as a simple dielectric region, as a trench or as a non-radiative emitter. The blind emitters 12 serve in particular to protect the laser bar 1 at the side surfaces. The region in the center of the laser bar 1 has only been indicated for clarity, but it is a simple continuation of the structures shown adjacent to it. The layer structure can deviate from that shown, in particular the n- and p-sides can be interchanged with regard to the substrate (p-substrate).

It can be seen that the individual laser elements are formed in a common layer structure, with structuring of the p-contact layer 10 for separation. The introduced separating structures 11 can be, in particular, ion implanted regions (first ion implantation zones), trenches or dielectric regions. Alternatively, the individual laser elements can also be separated by a corresponding structuring of an n-contact layer, by individual n-contacts or a p-contact layer and an n-contact layer. A laser bar 1 can typically comprise a number N of 5 to 200 laser elements n, wherein the laser elements can be designed as broad-strip lasers with a lateral width w of between 5 μm and 1200 μm, the length of the laser elements in the longitudinal direction is between about 2 mm and 6 mm, for example, and the distance d between the individual laser elements is typically about 30 μm to 100 μm.

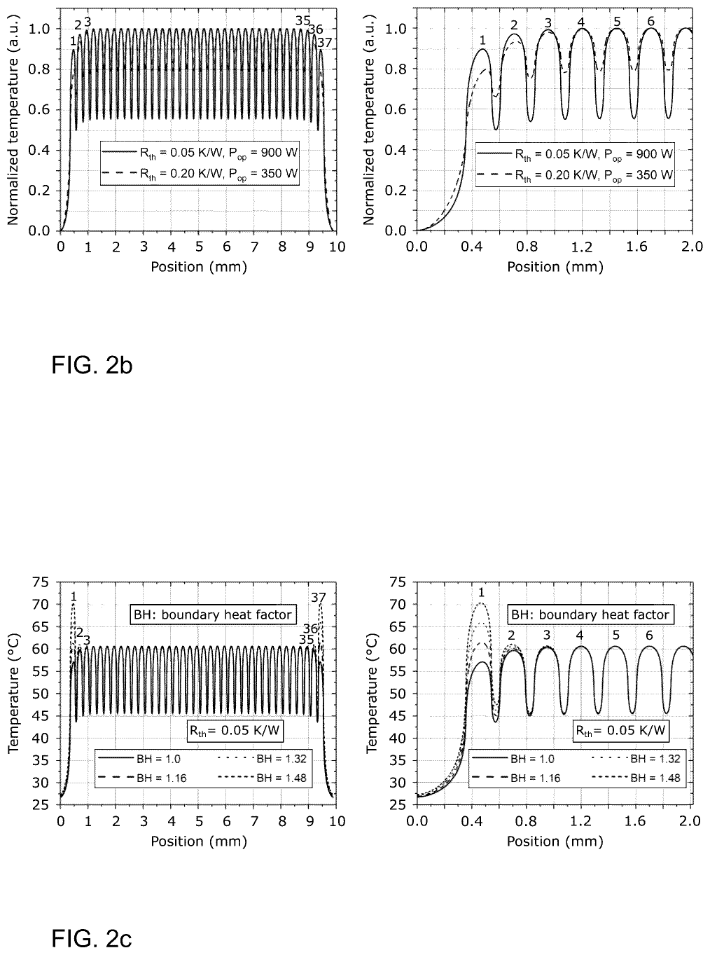

FIG. 2 shows a) lateral temperature profiles in conventional laser bars with 37 emitters for thermal resistances Rₜₕ of 0.05 K/W (left) and 0.20 K/W (right) at different operating powers Pop, b) normalized temperature profiles of the laser bars at their respective maximum operating points and c) the dependence of the lateral temperature profiles of a laser bar with Rth=0.05 K/W on the boundary heat factor BH of the outer emitter structures at their respective maximum operating points. In particular, these are temperature profiles of a kW-class laser bar at a dissipated thermal power loss P_{diss} of 603 W, wherein the power conversion efficiency was 60%. The individual laser elements had a spacing of 64 μm.

In FIGS. 2a and 2b, it can be seen that in particular the three laser elements located on the outside, respectively, have a lower temperature (equilibrium temperature between heat input by the laser process and heat output by corresponding cooling, measured in each case in the center of the active zone of the individual laser elements) than the inner laser elements during operation. With increasing thermal resistance Rₜₕ and corresponding increased equilibrium temperatures, the respective outer laser element in particular can have a maximum temperature that is up to 20% lower compared to the other laser elements of the laser bar. With a thermal resistance Rₜₕ of 0.2 K/W, the middle laser elements thereby show uniform temperatures between about 45° C. and 75° C., depending on the operating powers Pop. In the region between the individual laser elements, however, the temperature can drop by up to 45% compared with the respective maximum value, as shown by way of example in FIG. 2b.

FIG. 2c, on the other hand, shows that the lateral temperature profile of the laser bar can be modified by selectively increasing the power dissipation (i.e. the dissipated heat) at the edge emitters and thus achieving a uniform temperature distribution among the emitter structures in the bar. For this purpose, a so-called boundary heat factor BH of the respective outermost emitter structures was defined as a relative measure for estimating the strength of the required adjustment, which indicates by which factor the power dissipation P_{diss} of the outer emitter structures must be increased in order to obtain a largely homogeneous temperature profile.

In the example shown, boundary heat factor BH of 1.16 leads to an approximately homogeneous temperature distribution between the emitter structures. It should be noted that the boundary heat factor BH also acts on the inner emitter structures directly adjacent to the outermost emitter structures in each case and can therefore also influence their temperatures. Thus, an increase in the boundary heat factor BH can be used to compensate for the temperature drop of the emitter structures at the outer edges of a laser bar. In particular, a reduction of the lateral divergence angle of the total emission of the laser bar can be achieved by reducing a lensing effect occurring due to an asymmetric temperature profile.

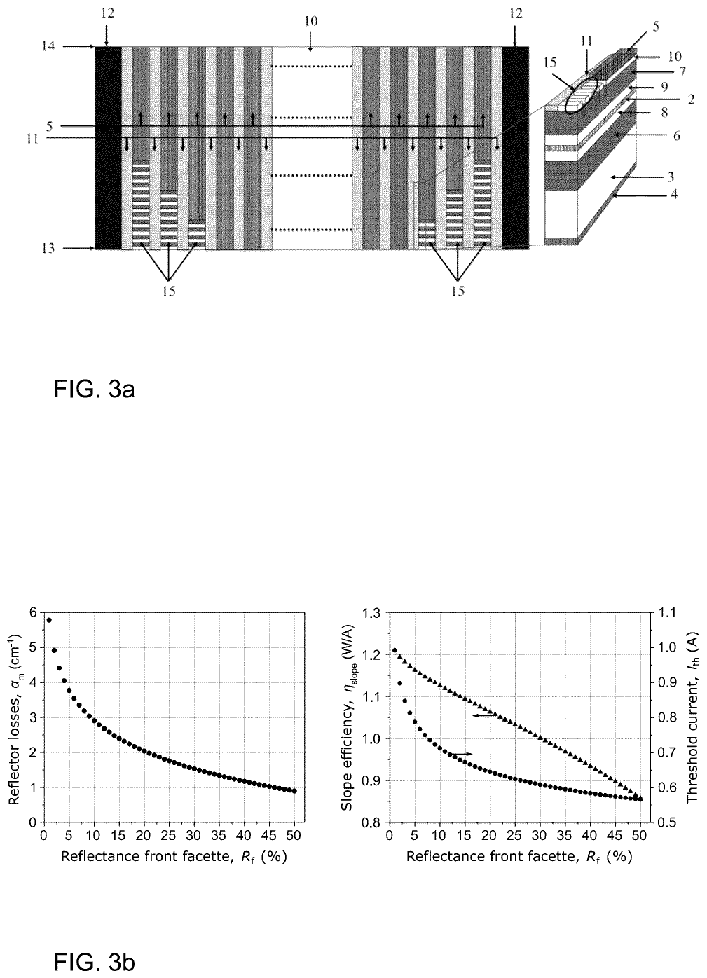

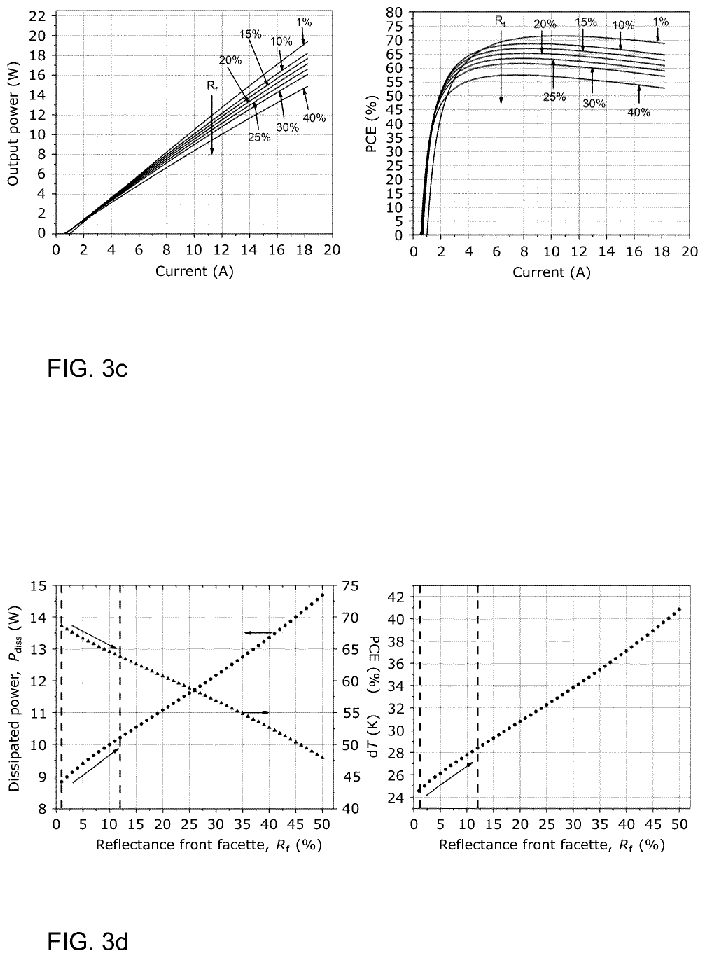

FIG. 3a shows a schematic representation of a first embodiment of a laser bar structure according to the invention in combined upward and oblique view. The basic structure of the layer system shown corresponds to that described for FIG. 1; the respective reference numerals and their assignment to individual features therefore apply accordingly.

To increase the temperature of the outer emitters of the laser bar, a distributed Bragg reflector (DBR) 15 was integrated into the structure in the region of the front facets 13 of these laser elements. Such DBR structures are known to the skilled person as feedback elements for spectral filtering of the emitted laser radiation, so that their implementation can be carried out without further ado with known technologies. The front-side DBR 15 shown is generated by a comb structure with trenches or a refractive index modulation corresponding to the trenches, which is arranged in the p-contact layer 10 and preferably extends into the p-cladding layer 7. Instead of the front-side DBR 15, dielectric mirroring of the front facets 13 can also be performed to form a reflector.

The structure of the DBR 15 or another reflector allows the reflectance R_{f} at the front facet 13 to be adjusted. This allows the optical properties of the resonator to be changed, reducing its decoupling losses. In the case of DBR 15, the reflectance R_{f} can be adjusted in particular via the number of layer pairs of the mirror. A higher reflectance R_{f} leads to a lower decoupling of laser radiation and a higher optical power within the emitter structure, i.e. inside the resonator formed between the front facet 13 and the rear facet 14, which consequently dissipates more power and results in a higher temperature within the emitter structure. Via an appropriate design of the reflectance R_{f} at the front facet 13 at the outer laser elements, the temperature of the outer laser elements can thus be adapted to the temperature level of the inner laser elements.

In the embodiment shown, the second and third outer laser elements have also been provided with a DBR 15 in the region of the front facets 13. The different lengths of the DBR structures shown are intended to indicate that the set reflectance R_{f} should decrease in the direction of the inner laser elements. However, the exact nature of the decrease function and how many laser elements on the outer sides are covered by it depends on the specific design of the laser bars 1 and the thermal coupling between the individual laser elements. The illustration of this embodiment is therefore purely exemplary and represents a variety of possible embodiments.

Regardless of the exemplary embodiment shown, the DBR used to increase the reflectance R and thus the thermal power dissipation that occurs can also be a rear-side reflector or the arrangement of the individual reflectors can be determined individually for each suitably modified laser element. In high-power laser bars in particular, however, a highly reflective rear-side reflector (e.g., a DBR or a dielectric mirror layer) is generally already present to increase the optical power coupled out on the front side, so that a further increase in reflectivity is no longer possible there.

FIG. 3b shows a dependence of the reflector losses, the slope efficiency ηₛₗₒₚₑ and the threshold current/th as a function of the reflectance R_{f} at the front facet. The reflector loss (αₘ in cm⁻¹) is the radiant power decoupled from the laser element by the reflector. With increasing reflectance R_{f} at the front facet, the reflector losses decrease strongly, with the strongest decrease already occurring at small reflectances R_{f} up to about 15%. A very similar behavior is shown by the threshold current Iₜₕ. The slope efficiency ηₛₗₒₚₑ, on the other hand, decreases approximately linearly with the reflectance R_{f} at the front facet.

FIG. 3c shows a dependence of the output power Pout and the power conversion efficiency PCE on the operating current I for different reflectances R_{f} at the front facet.

According to the dependencies shown in FIG. 3b, the achievable output powers Pout and the power conversion efficiencies PCE decrease with increasing reflectance R_{f}. On the other hand, however, this means that a larger proportion of the energy introduced into the laser elements is converted into heat loss and this can be used to adjust the temperature of the outer laser elements.

FIG. 3d shows a dependence of the dissipated power P_{diss}, the power conversion efficiency PCE and the temperature rise dT in the active zone as a function of the reflectance R_{f} at the front facet at maximum operating voltage (˜1.55 V). The power dissipation P_{diss} and the power conversion efficiency PCE show an opposite linear increase behavior, where with reflectances R_{f} between 1% and 50% at the front facet the power dissipation P_{diss} can be varied by a factor of 1.6. The dependence in the curve of the power dissipation P_{diss} can be directly assigned to a corresponding temperature increase dT within the active zone. In this case, with reflectances R_{f} between 1% and 50% at the front facet, temperature increases in the active region of between 24.5° C. and 41° C. related to the heat sink can be achieved. To compensate for the temperature deviation shown in FIG. 2 for Rₜₕ=0.05 K/W for the outer emitters of conventional laser bars, reflectances R_{f} between 1% and 12% would therefore be sufficient for the embodiment with front-side reflectors shown in FIG. 3a.

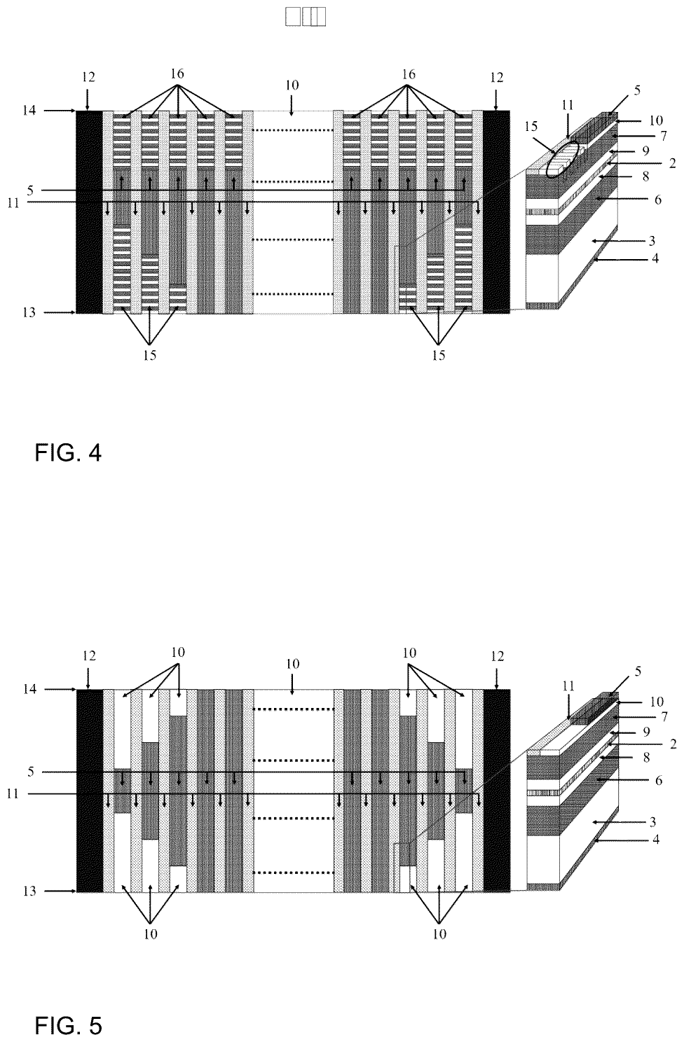

FIG. 4 shows a schematic representation of a second embodiment of a laser bar structure according to the invention in combined upward and oblique view. The basic structure of the layer system shown corresponds to that described for FIG. 3a; the respective reference numerals and their assignment to individual features therefore apply accordingly. In this embodiment, in addition to the front-side DBR 15 shown in FIG. 3a, rear-side DBR 16 are additionally arranged in the region of the rear facet 14. In contrast to the embodiment shown in FIG. 3a, optical feedback from spectrally narrowband DBR gratings is also possible here, which can produce a more stable and narrowband emission spectrum. The arrangement of the individual DBRs can also be reversed. It is also possible that the arrangement of the two DBR is determined individually for each correspondingly modified laser element.

FIG. 5 shows a schematic representation of a third embodiment of a laser bar structure according to the invention in combined upward and oblique view. The basic structure of the layer system shown corresponds to that described for FIG. 1; the respective reference numerals and their assignment to individual features therefore apply accordingly. In this embodiment, the length of the pumped region L_{gain} is shortened in the outer laser elements. This can be achieved, for example, by the fact that the metallic p-contact 5 resting on the p-contact layer 10 is not formed over the entire length Lᵣₑₛₒₙₐₜₒᵣ of the laser elements, but instead an injection of charge carriers takes place in each case only over a specific partial region. In the illustration shown, the three outer laser elements are adjusted accordingly in each case, with the length of the pumped regions L_{gain} decreasing towards the outside. The shortening is preferably symmetrical to both ends of the laser elements.

Shortening the length of the pumped regions L_{gain} leads to an increase in the electrical series resistance and thermal resistance. The increased series resistance reduces the maximum current flowing through the emitter structure. The significantly increased thermal resistance also increases the temperature within the emitter structures. The position of the pumped regions along the longitudinal axis of the emitter structures can be freely chosen and individually determined for different laser elements.

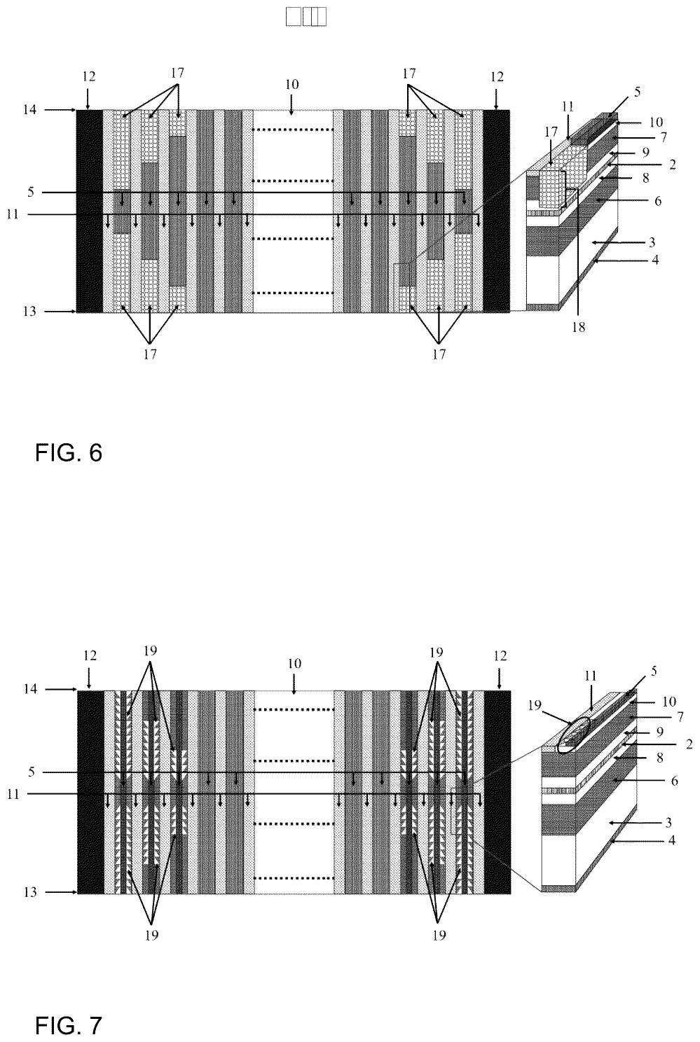

FIG. 6 shows a schematic representation of a fourth embodiment of a laser bar structure according to the invention in combined upward and oblique view The basic structure of the layer system shown corresponds to that described for FIG. 5; the respective reference numerals and their assignment to individual features therefore apply accordingly. In this embodiment, in addition to the shortening of the length of the pumped region L_{gain} shown in FIG. 5, was achieved by an additional implantation of inert ions in the non-pumped regions of the outer laser elements. This can suppress diffusion of charge carriers into the non-pumped regions. The depth 18 of these second implantation zones 17 thereby preferably extends from the p-contact layer 10 down into the p-waveguide layer 9.

FIG. 7 shows a schematic representation of a fifth embodiment of a laser bar structure according to the invention in combined upward and oblique view. The basic structure of the layer system shown corresponds to that described for FIG. 1; the respective reference numerals and their assignment to individual features therefore apply accordingly. In this embodiment, additional loss elements 19 are added as loss-inducing structures. The loss elements 19 can be, for example, 1-, 2- or 3-dimensional loss centers via a locally changed refractive index, etched wave-like structures along the longitudinal direction of the laser resonator, or crystal regions with locally increased charge carrier density, for example due to dopants diffusing in.

In the illustration, etched wave-shaped structures are shown as the example of loss elements 19. Such structures result in additional scattering and absorption losses due to interaction of the laser light at the loss centers. The resulting reduced slope efficiency of the emitter would increase the power dissipation and raise the temperature within the outer emitters. The shape and size of the loss centers is not limited to those shown in the figure. However, the loss elements 19 could be located elsewhere in the layer system. A reduction in the width of the p-contacts 5 is not necessary.

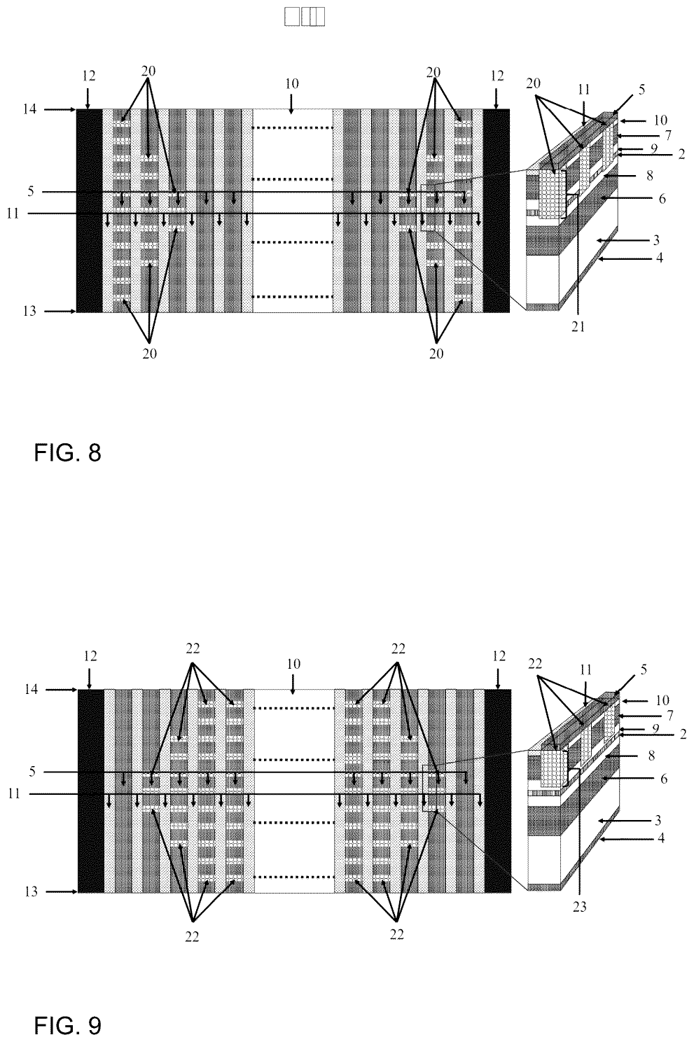

FIG. 8 shows a schematic representation of a sixth embodiment of a laser bar structure according to the invention in combined upward and oblique view. The basic structure of the layer system shown corresponds to that described for FIG. 1; the respective reference numerals and their assignment to individual features therefore apply accordingly. In this embodiment, inert ions are implanted at least in sections into the active layer 2 for the outer emitter structures. The depth 21 of these third implantation zones 20 can thereby preferably extend from the p-contact layer 10 through the active layer 2 down into the n-waveguide layer 8, more preferably down into the n-cladding layer 6. In an implanted region extending down to the active layer 2, the losses of injected charge carriers due to non-radiative recombination are significantly increased and thus the internal quantum efficiency ηᵢₙₜ is reduced. The injected charge carriers, which thereby recombine preferentially without radiation, thus increase the temperature of the respective emitter structure. For an effective reduction of the internal quantum efficiency by increasing the non-radiative recombination, it is preferred that the implantation extends beyond (or at least into) the active layer 2.

FIG. 9 shows a schematic representation of a seventh embodiment of a laser bar structure according to the invention in combined upward and oblique view. The basic structure of the layer system shown corresponds to that described for FIG. 1; the respective reference numerals and their assignment to individual features therefore apply accordingly. In this embodiment, inert ions are implanted at least in sections into the p-waveguide layer 9 in the case of the inner emitter structures. The depth 23 of these fourth implantation zones 22 can thereby preferably extend from the p-contact layer 10 down into the p-waveguide layer 9. In this embodiment, sections 22 provided with inert ions are introduced to increase the series resistance of the semiconductor layers. The resulting increased series resistance ρₛ (ρₛ>ρₛ₀) for the inner emitter structures forces a higher current flow through the outer emitter structures and, consequently, the temperature of the outer emitter structures can reach the temperature of the inner emitter structures in this embodiment as well.

### LIST OF REFERENCE NUMERALS

1 Laser bar
2 active layer
3 n-substrate
4 n-contact
p-contact
6 n-cladding layer
7 p-cladding layer
8 n-waveguide layer
9 p-waveguide layer
10 p-contact layer
11 separating structure (first ion implantation zone/trench/dielectric region)
12 blind emitter (dielectric region/trench/non-radiative emitter)
13 front facet
14 rear facet
15 front-side DBR
16 rear-side DBR
17 second ion implantation zone
18 depth of the second ion implantation zone
19 loss elements
20 third implantation zone
21 depth of the third implantation zone
22 fourth ion implantation zone
23 depth of the fourth implantation zone

What is claimed is:

1. A laser bar, comprising a layer system of a semiconductor material with an active layer, the layer system having an n-contact and p-contact for injecting charge carriers into the active layer, a plurality of emitter structures arranged in parallel next to one another being formed by structuring of the layer system, wherein the emitter structures extend in the longitudinal direction between a front facet and a rear facet and in the lateral direction from a first side to a second side and, for structuring, the emitter structures are separated from one another, respectively, by a separating structure extending in the longitudinal direction;
wherein for the variation of the temperature profile in lateral direction an adjustment of the dissipated thermal power of the outer emitter structures facing the first side and the second side, respectively, with respect to the inner emitter structures enclosed by the outer emitter structures is made.

2. The laser bar of claim 1, wherein an adjustment of the dissipated thermal power of the outer emitter structures has been made gradually across a plurality of adjacent outer emitter structures.

3. The laser bar of claim 1, wherein for increasing the dissipated thermal power the electrical and/or optical properties of the outer emitter structures are adjusted with respect to the inner emitter structures.

4. The laser bar of claim 1, wherein for increasing the light intensity circulating in the emitter structures, in the outer emitter structures the facet reflectivity is increased with respect to the facet reflectivity of the inner emitter structures.

5. The laser bar of claim 4, wherein the facet reflectivity of the emitter structures is adjusted by reflectors by means of an integration of front-side DBR and/or rear-side DBR, or by applying dielectric mirror layers to the front facets and/or the rear facets.

6. The laser bar of claim 5, wherein the reflectivity of a front-side reflector of the outer emitter structures is between 1% and 30%.

7. The laser bar of claim 1, wherein, in order to increase the series resistance as well as the thermal resistance of the outer emitter structures with respect to the inner emitter structures, the length of the pumped region is shortened with respect to the length of the pumped region of the inner emitter structures by forming non-pumped regions.

8. The laser bar of claim 1, wherein for the outer emitter structures the length of the pumped region with respect to the length of the pumped region of the inner emitter structures is between 90% and 30%.

9. The laser bar of claim 7, wherein to reduce charge carrier propagation at the non-pumped passive regions are inert ions implanted by deep ion implantation.

10. The laser bar of claim 1, wherein loss elements are formed to increase the internal optical losses at the outer emitter structures.

11. The laser bar of claim 10, wherein the internal optical losses of the outer emitter structures are between 0.6 cm⁻¹ and 1.5 cm⁻¹.

12. The laser bar of claim 1, wherein to increase the thermal power of the outer emitter structures with respect to the inner emitter structures, for the outer emitter structures inert ions are implanted at least in sections in the direction of the active layer to increase the non-radiative recombination and thus to reduce the internal quantum efficiency.

13. The laser bar of claim 12, wherein the internal quantum efficiencies of the outer emitter structures are between 50% and 92%.

14. The laser bar of claim 1, wherein to increase the series resistance of the inner emitter structures inert ions are implanted at least in sections in the direction of the active layer.

15. The laser bar of claim 14, wherein the series resistance of the inner emitter structures is increased by a factor of 1.2 to 1.6 compared to the series resistance of the outer emitter structures.

16. The laser bar of claim 1, wherein a largely homogeneous temperature profile with respect to the maximum temperature of the individual emitter structures during operation of the laser is set by the adjustment in the lateral direction.

17. The laser bar of claim 16, wherein the plurality of emitter structures is arranged equidistantly with uniform width.
